(19) United States
(12) Patent Application Publication
(10) Pub. No.: US 2015/0333753 A1
(43) Pub. Date: Nov. 19, 2015

(54) IO AND PVT CALIBRATION USING BULK INPUT TECHNIQUE

(71) Applicants: Shih-Lun Chen, Taipei (TW); Ming-Jing Ho, Hsinchu (TW); Wei-Cheng Hsieh, Hsinchu (TW)

(72) Inventors: Shih-Lun Chen, Taipei (TW); Ming-Jing Ho, Hsinchu (TW); Wei-Cheng Hsieh, Hsinchu (TW)

(73) Assignees: Taiwan Semiconductor Manufacturing Company LTD., HSINCHU (TW); GLOBAL UNICHIP CORP., HSINCHU (TW)

(21) Appl. No.: 14/279,317

(22) Filed: May 16, 2014

(51) Int. Cl. H03K 19/00; H03K 19/003

(52) U.S. Cl. CPC H03K 19/0005; H03K 19/00384

(57) ABSTRACT

The present invention discloses an efficient way to match the impedance between a pull-up path and a pull-down path of an IO cell without using stacked devices on the output stage of the IO cell to save area and to achieve higher speed; back-gate (bulk or body) voltages of a pull-up transistor and a pull-down transistor of the IO cell can be respectively adjusted to a value to achieve the desired impedance values of the pull-up and pull-down paths. A central calibration unit can generate an impedance calibration code and distribute them to a local adjustable bias generator in each IO cell groups, wherein the local adjustable bias generator, which is embedded in a power or a ground pad, receives the impedance calibration code and generates bias voltages to the back-gates of the pull-up and pull-down transistors for setting impedance values of the pull-up and pull-down paths, respectively.

### BACKGROUND OF THE INVENTION

1. Field of the Invention

The present invention relates generally to a circuit design, and more particularly to an off chip driver and an on die termination circuit design.

2. Description of the Prior Art

When a signal is transmitted through two transmission lines having different impedances, a part of the transmitted signal may be lost. Further, the amount of signal loss may increase as the speed of signal transmission increases. Therefore, in a semiconductor device that has a driver to transmit a signal to an external transmission line, the output impedance of the driver should be matched with the impedance of the external transmission line.

A semiconductor device that transmits a signal at high speed through a transmission line may include an off-chip driver (OCD) and an on-die-termination circuit (ODT) for impedance matching with an external transmission line. An OCD may perform an impedance matching operation to transmit the signal to minimize loss when the signal is outputted from the semiconductor device to the exterior. An ODT may perform an impedance matching operation to minimize loss when the signal is inputted from the exterior to the semiconductor device.

An impedance characteristic of the OCD or the ODT may be calibrated to obtain a higher degree of signal integrity. The need for impedance calibration increases as the speed of signal transmission increases.

For high-speed IO signals such as signals in a double-data-rate (DDR) memory interface, process-voltage-temperature (PVT) variations will impact the impedance characteristics of IO pads significantly; therefore an efficient way to compensate the PVT variations to achieve a desired performance for each IO pad is very important.

In a conventional IC design, the body or bulk of a PMOS transistor is tied to VDD and that of a NMOS transistor is tied to ground.

FIG. 1 shows a conventional analog-type OCD/ODT design. The pull-up driver includes P0 42 and P1 46, and the pull down driver includes N1 48 and N0 44. The output signal is at the joined point of P1 46 and N1 48. Input data couples to the gates of P1 46 and N1 48 through an inverter 50. An impedance evaluation circuit 31 generates PBIAS to the gate of P0 42 and NBIAS to the gate of N0 44 to adjust the impedance of the pull-up path and the pull-down path. However, the pull-up path and the pull-down path require stacking transistors as shown in FIG. 1.

FIG. 2 shows another conventional analog-type OCD/ODT design. P0 and N0 are biased devices. An impedance evaluation circuit 31 generates PBIAS to a gate of P0 through N2 60 and NBIAS to a gate of N0 through P2 62 to adjust the impedance of the pull-up path and the pull-down path. P1 and N1 are the switches for conducting the pull-up and pull-down paths. Gate voltages of P0 and N0 can be adjusted so as to make the pull-up and pull-down paths have the same impedance. However, the bias circuit must provide large driving capacity for PBIAS and NBIAS.

FIG. 3 shows a conventional binary-weight digital-type OCD/ODT design with an output stage. PU0˜PUS and PD0˜PDS can be controlled so as to make the pull-up and pull-down paths have the same impedance.

It is noted that the conventional analog analog-type OCD/ODT designs require stacking transistors, and that the conventional digital OCD/ODT design requires many parallel paths of resistors and transistors. Consequently, the use of a relatively large number of resistors or transistors may result in an integrated circuit that is physically large. Additionally, the presence of the number of resistors or transistors may make it more difficult to route in the integrated circuit.

Therefore, what is needed is an effective and efficient way to design an IO cell with desired OCD/ODT impedance values to increase signal integrity.

### SUMMARY OF THE INVENTION

One objective of present invention is to provide an efficient way to match the impedance between a pull-up path and a pull-down path without using stacked devices on the output stage of an IO cell to save area and to achieve higher speed.

One embodiment of present invention is to provide an efficient way to adjust back-gate (bulk or body) voltages of a pull-up transistor and a pull-down transistor to achieve the desired off chip driver (OCD) or on die termination (ODT) impedance values.

One embodiment of present invention is to provide an efficient way to adjust back-gate (bulk) voltages of a pull-up transistor and a pull-down transistor to compensate impedance variations of the pull-up and the pull-down paths due to PVT variations. A central PVT calibration unit can re-generate the local VBP and VBN and distribute them to IO cell groups, wherein a local bias generator in each IO cell group can be embedded in a VDD or a VSS pad, and a bias control bus can be used for communications between the central PVT calibration unit and the local bias generators.

In one embodiment, a driver circuit having an output node for transmitting a signal is disclosed, wherein the driver circuit comprises: a first pull-up driver having a first terminal coupled to a first reference voltage and a second terminal coupled to the output node, and the first pull-up driver comprises a pull-up transistor having a first bulk voltage node, wherein a pull-up path is formed between the first terminal and the second terminal when the pull-up transistor is on; a first pull-down driver having a third terminal coupled to the output node and a fourth terminal coupled to a second reference voltage, and the first pull-down driver comprises a pull-down transistor having a second bulk voltage node, wherein a pull-up path is formed between the third terminal and the fourth terminal when the pull-down transistor is on; and a first adjustable bias generator for generating a first bias voltage to the first bulk voltage node and a second bias voltage to the second bulk voltage node, respectively, such that a first impedance of the pull-up path and a second impedance of the pull-up path are substantially the same to reduce transmission loss of the signal.

In one embodiment, the pull-up transistor is a PMOS transistor and the pull-down transistor is a NMOS transistor.

In one embodiment, the driver circuit described above comprises a calibration unit for adjusting the first bias generator so as to compensate impedance variations of the pull-up and the pull-down paths due to PVT variations.

In one embodiment, the driver circuit described above further comprises a calibration unit, wherein the calibration unit is configured to control the first adjustable bias generator to generate the first bias voltage and the second bias voltage such that the first impedance and the second impedance are substantially the same corresponding to an impedance of a reference resistor.

In one embodiment, a semiconductor device is disclosed, wherein the semiconductor device comprises: a plurality of groups of pads, wherein each group comprises a power pad or a ground pad and a plurality of IO pads, wherein an adjustable bias generator is embedded in the power pad or the ground pad of the group of pads, and each of the plurality of IO pads has a pull-up driver and a pull-down driver; a PVT calibrating unit configured to generate an impedance calibration code corresponding to an impedance of a reference resistor and output the impedance calibration code to the adjustable bias generators through a bias control bus; and wherein for each group of pads the adjustable bias generator of the group of pads generates bias voltages to condition impedances of the pull-up driver and the pull-down driver of the plurality of IO pads of the group, respectively, according to the impedance calibration code.

### BRIEF DESCRIPTION OF DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 illustrates a conventional analog-type OCD/ODT design;

FIG. 2 illustrates another conventional analog-type OCD/ODT design;

FIG. 3 illustrates a conventional digital-type OCD/ODT design;

FIG. 4 illustrates an OCD/ODT design in accordance with one embodiment of the invention.

FIG. 5 illustrates a PVT calibration design in accordance with one embodiment of the invention; and

FIG. 6 shows a PVT calibration unit that share its results to many IOs in accordance with one embodiment of the invention.

### DETAILED DESCRIPTION OF EMBODIMENT

The detailed explanation of the present invention is described as following. The described preferred embodiments are presented for purposes of illustrations and description, and they are not intended to limit the scope of the present invention.

In traditional IC design, the bulk (back-gate) of PMOS is tied to VDD and that of NMOS is tied to ground. In today's advanced processes, it is possible to control the back-gate (bulk) voltages of PMOS and NMOS. This invention uses back-gate (bulk) input technique to design a PVT IO cell, allowing the size of the PVT IO cell to be reduced effectively and suitable for low-voltage and/or high speed applications.

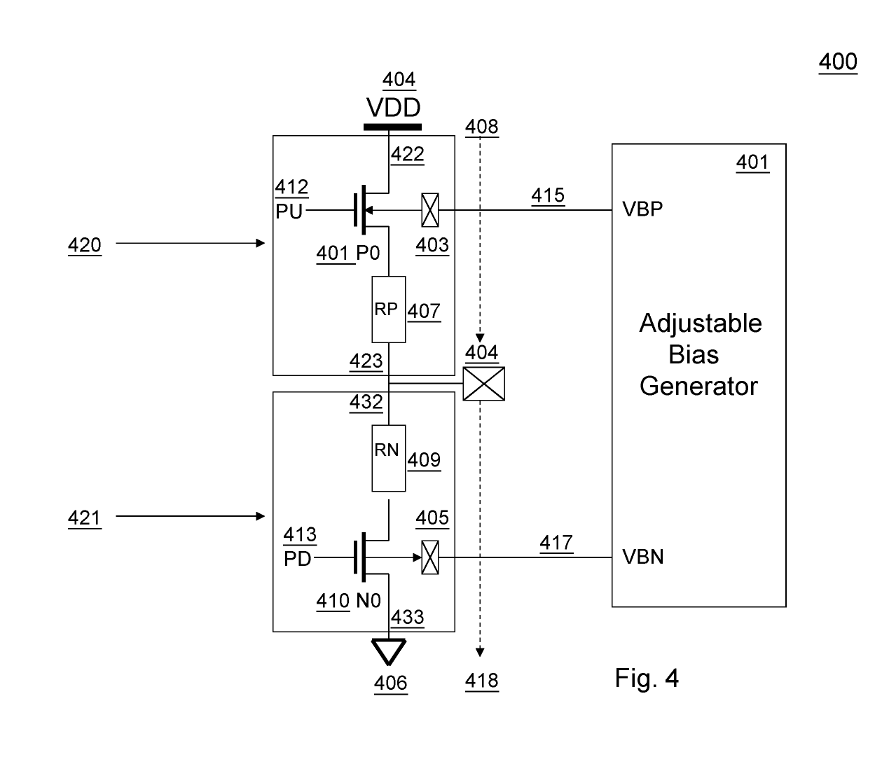

FIG. 4 illustrates OCD/ODT design in accordance with one embodiment of this invention. As shown in FIG. 4, a pull-up driver 420 having a first terminal 422 and a second terminal 423, wherein the first terminal 422 is coupled to a first reference voltage VDD 404 and the second terminal 423 is coupled to the output node 404, and the pull-up driver 420 comprises a pull-up transistor such as a PMOS transistor P0 401 and a resistor RP 407, wherein the PMOS transistor P0 401 has a first bulk voltage node 403 and a gate driven by a signal PU 412 to turn on the PMOS transistor P0 401, wherein a pull-up path 408 is formed from the first reference voltage VDD 404 to the output node 404 through the pull-up driver 420 when the PMOS transistor P0 401 is on; a pull-down driver 421 having a third terminal 432 and a fourth terminal 433, wherein the third terminal 432 is coupled to the output node 404 and the fourth terminal 433 is coupled to a second reference voltage GND 406, and the pull-down driver 421 comprises a pull-down transistor such as a NMOS transistor N0 410 and a resistor RN 409, wherein the NMOS transistor N0 410 has a second bulk voltage node 405 and a gate driven by a signal PD 413 to turn on the NMOS transistor N0 410, wherein a pull-down path 418 is formed from the output node 404 to the second reference voltage GND 406 through the pull-down driver 421 when the NMOS transistor N0 410 is on; and a first adjustable bias generator 401 for generating a first bias voltage VBP 415 to the first bulk voltage node 403 and a second bias voltage VBN 417 to the second bulk voltage node 405, wherein each of the first bias voltage VBP 415 and the second bias voltage VBN 417 is adjusted to a first value such that the pull-up path 408 and the pull-down path 418 have substantially the same impedance. In other words, the impedance between the first terminal 422 and the second terminal 423 of the pull-up driver 420 is substantially the same as the impedance between the third terminal 432 and the fourth terminal 433 of the pull-down driver 421.

Please note the pull-up and pull-down drivers can be in other suitable forms as long as a pull-up path and a pull-down path can be formed by turning on the pull-up and pull-down transistors respectively.

Please note that a bulk voltage node is also referred as a back-gate of the PMOS or NMOS transistor. In summary, the VBP 415 and VBN 417 are back-gate (bulk or body) voltages of PMOS and NMOS, and VBP 415 and VBN 417 are respectively adjusted to achieve the desired OCD/ODT impedance values to reduce transmission loss of the signal transmitted by the output node 404. Please note that, for an OCD/ODT pad, the output node can transmit a signal in a first operation; and the output node will be turned into an input node to receive a signal in a second operation.

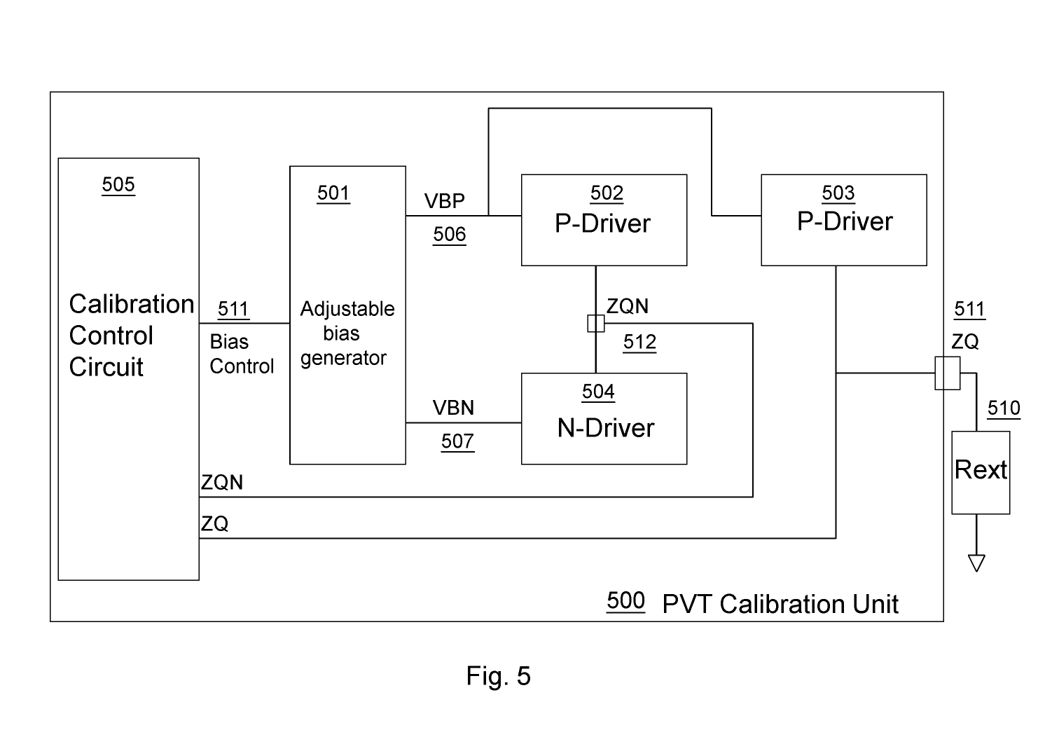

The OCD (on-chip driver) and ODT (on-die termination) calibration is a very important feature in high-speed interfaces, such as a DDR SDRAM interface. The OCD/ODT calibration usually uses an external precise resistor as the reference resistor to adjust the OCD/ODT circuits. FIG. 5 illustrates a PVT calibration unit design in accordance with one embodiment of the invention. As shown in FIG. 5, a PVT calibration unit 500 including a adjustable bias generator 501 which is the same as shown in FIG. 4, a first p-driver 502, a second p-driver 503, one n-driver 504 and a calibration control circuit 505. The p-driver 502, 503 and n-driver 504 are the same as the pull-up driver and pull-down driver in FIG. 4 respectively. An external precise resistor (Rext) 510 is in series with the second p-driver 503 for adjusting the bulk voltages of the p-driver 502, 503 and n-driver 504. The bias generator 501 can generate the VBP 506 and VBN 507 to control the bulk voltage of the p-drivers 502, 503 and the bulk voltage of the n-driver 504, respectively. The calibration control circuit 505 detects the ZQ 511 and ZQN 512 voltages and then adjusts the VBP 506 and VBN 507 accordingly. For ex-ample, when the VBP 506 is adjusted to a value such that the ZQ 511 voltage is at half of the VDD voltage, the impedance of the pull-up path of the second p-driver 503 will be equal to the resistance of the Rext. Then, the VBN 507 can be adjusted to a value such that the ZQN 512 voltage is at half of the VDD voltage to match the impedance of the pull-down path of the n-driver 504 to the impedance of the pull-up path of the first p-driver 502. Finally, the pull-up path of the p-driver 502, 503 and the pull-down path of the n-driver 504 have the same impedance corresponding to the impedance of the external precise resistor (Rext) 510. Please note that the impedance of the external precise resistor (Rext) 510 can be selected based on applications. Please note that the PVT calibration unit 500 can be implemented for each IO pad locally. However, it will require too many calibration units for an IC design that has many IO pads.

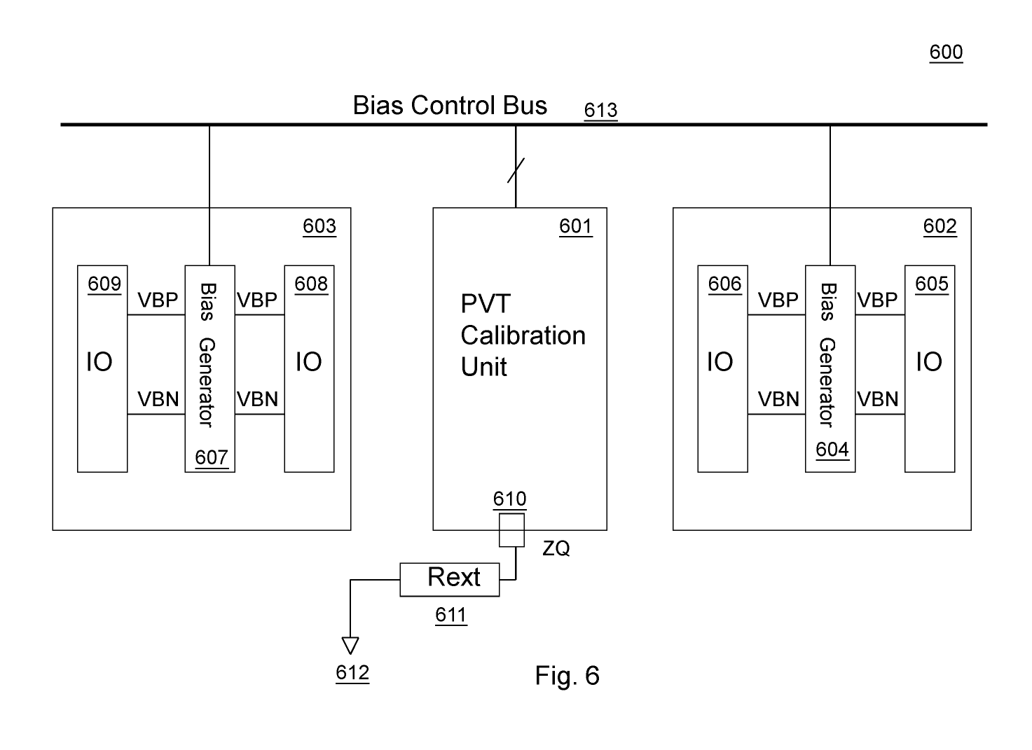

FIG. 6 shows a block diagram 600 in which a PVT calibration unit shares its results to many IOs. A PVT calibration unit 601 which is the same as shown in FIG. 5 is connected to many IO groups such as IO group 602, 603. The PVT calibration unit 601 connected to a external reference resistor Rext 611 to GND 612 through an output node ZQ 610. JO group 602 has a local bias generator 604 and two IO cells or pads 605, 606; and IO group 603 has a local bias generator 607 and two IO cells or pads 608, 609. Please note that each IO group can have any number of IO cells, and it is not limited to two cells. Because calibration results are digital codes which will be denoted as impedance calibration code hereafter, they can be delivered to very long distances. A local bias generator similar to the bias generator inside the PVT calibration unit can re-generate the local VBP and VBN to IO cells in a group. As a result, one IO group only needs one local bias generator. In this way, in IC designs with a large pin count, the impedance calibration code of the bias generator can be transmitted from the PVT calibration unit 601 to all the IO groups 602, 603 through a bias control bus 613.

In one embodiment, a local bias generator in each IO cell group can be embedded in a VDD or a VSS pad, and a bias control bus can be used for communications between the central PVT calibration unit and the local bias generators. As shown in FIG. 6, each of the local bias generator 604, 607 is located in a power pad or a ground pad respectively.

In one embodiment, a semiconductor device is disclosed, wherein the semiconductor device comprises: a plurality of groups of pads, wherein each group comprises a power pad or a ground pad and a plurality of IO pads, wherein for each group of pads an adjustable bias generator is embedded in the power pad or the ground pad of the group of pads, and each of the plurality of IO pads has a pull-up driver and a pull-down driver; a PVT calibrating unit configured to generate an impedance calibration code corresponding to an impedance of a reference resistor and output the impedance calibration code to each adjustable bias generator through a bias control bus; and wherein for each group of pads the adjustable bias generator of the group of pads generates bias voltages to condition impedances of the pull-up driver and the pull-down drive of the plurality of IO pads of the group, respectively, according to the impedance calibration code. Please note that each IO pad can be an OCD/ODT pad which can transmit and receive a signal at different times or an ODT pad which can only receive a signal.

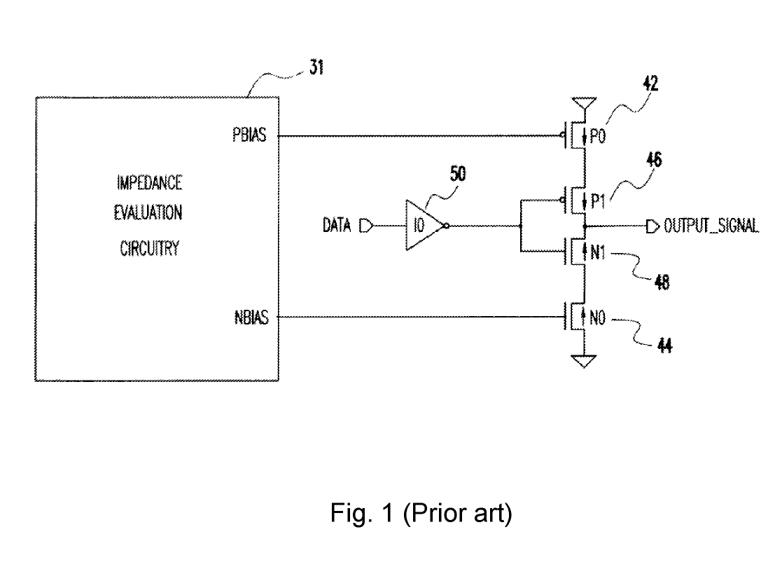

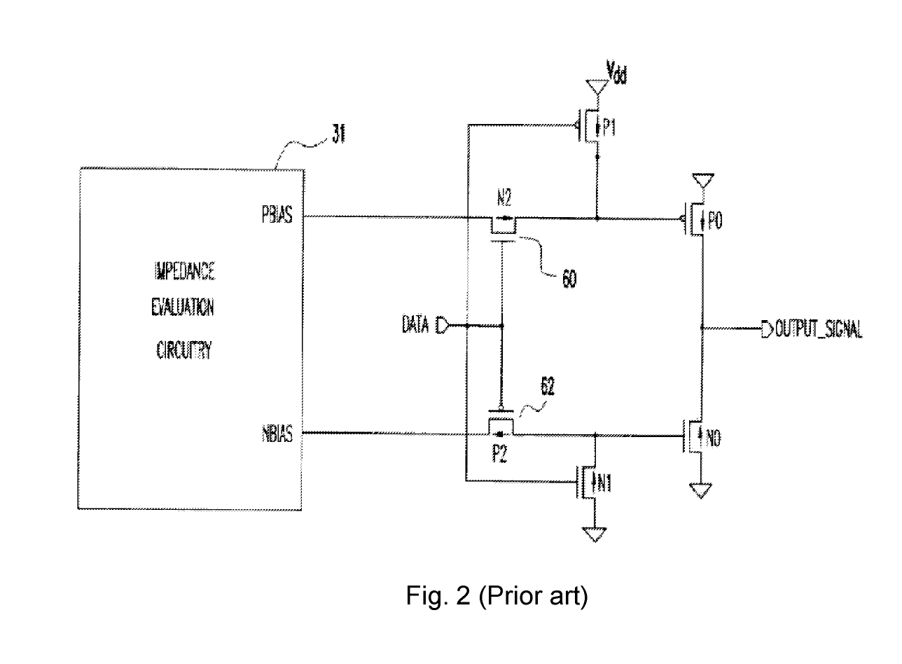

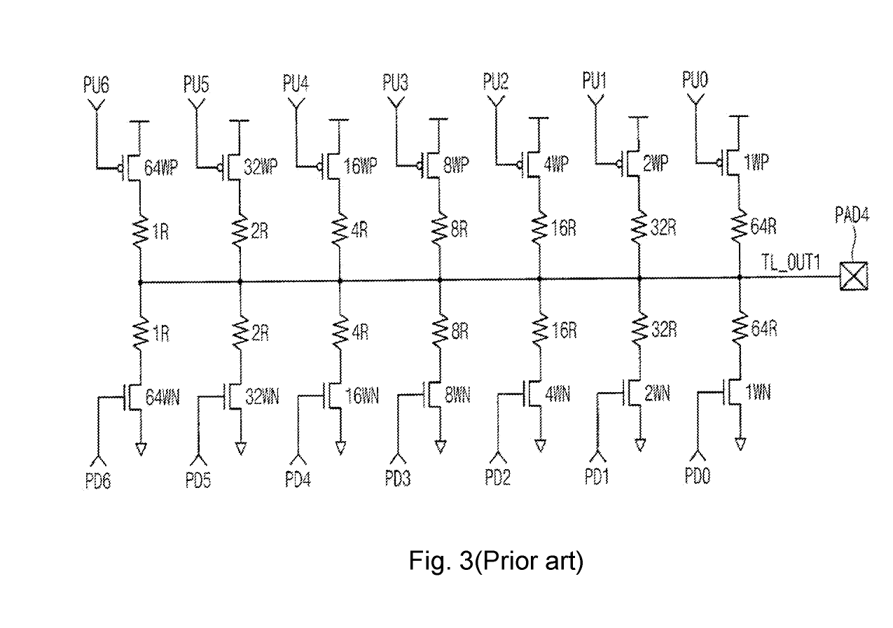

In one embodiment, in the above-mentioned semiconductor device, the pull-up driver and the pull-down driver are the same as those divers in FIG. 4, wherein the pull-up driver has comprises a pull-up transistor having a first bulk voltage node, and the pull-down driver comprises a pull-down transistor having a second bulk voltage node, wherein the adjustable bias generator of the group of pads generates a first bias voltage to the first bulk voltage node and a second bias voltage to the second bulk voltage node according to the impedance calibration code. However, it is note that the impedance calibration architecture of the above-mentioned semiconductor device can be applied to conventional OCT/ODT designs in FIG. 1-3 as well. The details of descriptions of the above semiconductor device can be understood from FIG. 4-6; therefore, it will not be described further.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

1. A circuit having an output node for transmitting a signal, comprising:
a first pull-up driver having a first terminal coupled to a first reference voltage and a second terminal coupled to the output node, and the first pull-up driver comprises a pull-up transistor having a first bulk voltage node, wherein a pull-up path is formed between the first terminal and the second terminal when the pull-up transistor is on;
a first pull-down driver having a third terminal coupled to the output node and a fourth terminal coupled to a second reference voltage, and the first pull-down driver comprises a pull-down transistor having a second bulk voltage node, wherein a pull-down path is formed between the third terminal and the fourth terminal when the pull-down transistor is on; and
a first adjustable bias generator for generating a first bias voltage to the first bulk voltage node and a second bias voltage to the second bulk voltage node, respectively, such that a first impedance of the pull-up path and a second impedance of the pull-down path are substantially the same to reduce transmission loss of the signal.

2. The circuit according to claim 1, wherein the first bias voltage to the first bulk voltage node and the second bias voltage to the second bulk voltage node are adjusted to compensate PVT variations of the first impedance and the second impedance.

3. The circuit according to claim 1, wherein the pull-up transistor is a PMOS transistor and the pull-down transistor is a NMOS transistor.

4. The circuit according to claim 1, further comprising a calibrating circuit configured to control the first adjustable bias generator to generate the first bias voltage and the second bias voltage such that the first impedance and the second impedance are substantially the same corresponding to an impedance of a reference resistor.

5. The circuit according to claim 4, wherein the calibration unit comprises a second pull-up driver, a third pull-up driver, a second pull-down driver and a calibration control circuit, wherein the second pull-up driver is in series with the second pull-down driver at a first detecting node, and the third pull-up driver is in series with a reference resistor at a second detecting node, wherein the calibration control circuit detects the voltages at the first and second detecting node for generating the first bias voltage and the second bias voltage.

6. The circuit according to claim 5, wherein the calibration unit further comprises a second adjustable bias generator, wherein the calibration control circuit detects the voltages at the first and second detecting node to generate an impedance calibration code to set the second adjustable bias generator such that the second pull-up driver and the second pull-down driver have substantially the same impedance corresponding to the reference resistor and transmits the impedance calibration code to the first adjustable bias generator to generate the first bias voltage and the second bias voltage.

7. The circuit according to claim 6, wherein the first adjustable bias generator is embedded in a power or a ground pad.

8. A semiconductor device, comprising: a plurality of IO pads, wherein each IO pad comprises the circuit recited in claim 1.

9. A semiconductor device, comprising:
a plurality of groups of pads, wherein each group comprises a power pad or a ground pad and a plurality of IO pads, wherein a first adjustable bias generator is embedded in the power pad or the ground pad of the group of pads, and each of the plurality of IO pads has a first pull-up driver and a first pull-down driver;
a calibrating unit configured to generate an impedance calibration code corresponding to an impedance of a reference resistor and output the impedance calibration code to the first adjustable bias generators through a bias control bus;
wherein, for each group of pads, the first adjustable bias generator of the group of pads generates bias voltages to condition impedances of the first pull-up driver and the first pull-down driver of the plurality of IO pads of the group, respectively, according to the impedance calibration code.

10. The semiconductor device according to claim 9, wherein the first pull-up driver has comprises a pull-up transistor having a first bulk voltage node, and the first pull-down driver comprises a pull-down transistor having a second bulk voltage node, wherein the first adjustable bias generator of the group of pads generates a first bias voltage to the first bulk voltage node and a second bias voltage to the second bulk voltage node according to the impedance calibration code.

11. The semiconductor device according to claim 10, wherein the pull-up transistor is a PMOS transistor and the pull-down transistor is a NMOS transistor.

12. The semiconductor device according to claim 10, wherein the calibration unit comprises a second pull-up driver, a third pull-up driver, a second pull-down driver, a second adjustable bias generator and a calibration control circuit, wherein the second pull-up driver is in series with the second pull-down driver at a first detecting node, and the third pull-up driver is in series with a reference resistor at a second detecting node, wherein the calibration control circuit detects the voltages at the first and second detecting node to generate an impedance calibration code to set the second adjustable bias generator such that the second pull-up driver and the second pull-down driver have substantially the same impedance corresponding to the reference resistor and transmits the impedance calibration code to the first adjustable bias generator of the group of pads for generating the first bias voltage to the first bulk voltage node and the second bias voltage to the second bulk voltage node.

13. The semiconductor device according to claim 10, wherein the first bias voltage to the first bulk voltage node and the second bias voltage to the second bulk voltage node are adjusted to compensate PVT variations.
